(19) United States
(12) Patent Application Publication
(10) Pub. No.: US 2026/0361310 A1
(43) Pub. Date: Nov. 12, 2026

(54) LC OSCILLATOR COUPLED TO FRACTIONAL FREQUENCY DIVIDER AND RESONANT CLOCK DRIVER

(71) Applicant: Advanced Micro Devices, Inc., Santa Clara, CA (US)

(72) Inventors: Lyn Mark ELZINGA, Folsom, CA (US); Xiaoye JING, Santa Clara, CA (US); Dirk J. ROBINSON, Fort Collins, CO (US)

(21) Appl. No.: 19/202,975

(22) Filed: May 8, 2025

(51) Int. Cl. H03L 7/099; H03B 5/12; H03L 7/197

(52) U.S. Cl. CPC H03L 7/0994; H03B 5/1275; H03L 7/1976

(57) ABSTRACT

Embodiments herein describe a circuit including an LC oscillator configured to receive a frequency control signal, a fractional frequency divider coupled to the LC oscillator, and a resonant clock driver coupled to the fractional frequency divider, the resonant clock driver configured to mitigate duty cycle error (DCE) introduced by the fractional frequency divider. The fractional frequency divider divides in ratios including 1, as well as 1+N*step, where step is a fraction including 0.25 or 0.5 or other fraction, and N is an integer value greater than zero. The resonant clock driver removes phase noise and deterministic jitter introduced by the fractional frequency divider. The resonant clock driver filters phase noise, duty cycle distortion, and unwanted harmonics to maintain a duty cycle within a predetermined range.

### TECHNICAL FIELD

Examples of the present disclosure generally relate to circuits, and, in particular, to an LC oscillator coupled to a fractional frequency divider and a resonant clock driver.

### BACKGROUND

In the design of LC oscillators, a challenge arises due to the tradeoff between phase noise performance, frequency tuning range, and power consumption, often referred to as the figure of merit including tuning (FOMT). The FOMT represents the balance between these competing factors, where a higher frequency tuning range results in increased phase noise and power consumption. This occurs because the tuning range increase requires additional or larger tuning devices such as varactors, or digitally tuned capacitors or digitally tuned inductors that degrade the quality factor and signal to noise ratio of the oscillator. As such, achieving a low phase noise while maintaining a broad tuning range involves compromises in performance.

Additionally, power consumption is another aspect that impacts the efficiency and practicality of LC oscillators in various applications. To minimize power consumption, designers need to sacrifice some of the oscillator's tuning flexibility or phase noise performance, further complicating the design process. These tradeoffs lead to a reduced FOMT, making it difficult to simultaneously optimize phase noise, tuning range, and power consumption without degrading overall performance. This challenge necessitates innovative solutions that can balance these factors to improve the efficiency and accuracy of frequency generation in advanced clocking systems.

### SUMMARY

One example described herein is a circuit including an LC oscillator configured to receive a frequency control signal, a fractional frequency divider coupled to the LC oscillator, and a resonant clock driver coupled to the fractional frequency divider, the resonant clock driver configured to mitigate duty cycle error (DCE) introduced by the fractional frequency divider.

One example described herein is a circuit including an LC oscillator coupled to a fractional frequency divider and a tunable resonant clock driver coupled to the fractional frequency divider, the tunable resonant clock driver configured to act as a bandpass filter to maintain a duty cycle within a predetermined range.

One example described herein is a method including generating a frequency control signal, setting an LC oscillator frequency dictated by the frequency control signal, adjusting the LC oscillator frequency using a fractional frequency divider, and filtering phase noise and maintaining a duty cycle within a predetermined range using a resonant clock driver acting as a bandpass filter, the resonant clock driver controlled by a frequency select signal.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a circuit including an LC oscillator, a fractional frequency divider, and a resonant clock driver, according to an example.

FIG. 2 illustrates a resonant clock driver, according to an example.

FIG. 3A illustrates a table with divide ratios, according to an example.

FIG. 3B illustrates a fractional frequency divider, according to an example.

FIG. 3C illustrates a timing diagram, according to an example.

FIG. 4 illustrates a method for implementing the circuit including the LC oscillator, the fractional frequency divider, and the resonant clock driver, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the examples herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

In the development of high-frequency clock generation systems, an LC oscillator remains a key component due to its excellent phase noise performance and low jitter characteristics. An LC oscillator is a circuit that generates a continuous, sinusoidal oscillation at a specific frequency using an inductor (L) and a capacitor (C).

However, LC oscillators present challenges in achieving an optimal balance between frequency tuning range, phase noise, and power consumption. Frequency tuning range refers to the span of frequencies over which a system, such as an LC oscillator, can be adjusted while maintaining stable operation. Phase noise refers to random fluctuations in the phase of a signal, causing spectral spreading around the carrier frequency.

This tradeoff is often quantified by the figure of merit including tuning (FOMT), which evaluates the efficiency of the oscillator design across these competing parameters. The goal of an efficient LC oscillator design is to maximize the frequency range and minimize phase noise and power consumption simultaneously, but these goals often conflict with each other, limiting the practical performance of the LC oscillator in high-speed applications.

To address these limitations, various solutions have been proposed to improve the FOMT of LC oscillators. One typical approach is the use of a cascaded LC phase-locked loop (PLL) with multiple instances of ring oscillators. This approach improves frequency stability and jitter performance by utilizing multiple stages of oscillation. However, this solution fails to meet the performance requirements for high-speed applications such as, e.g., 224G Ethernet, which refers to the next-generation ultra-high-speed Ethernet standard targeting 224 Gbps per lane for data transmission. While the use of ring oscillators provides faster switching times, ring oscillators introduce higher levels of phase noise and deterministic jitter, making ring oscillators unsuitable for precision clock generation in modern communication systems.

Another typical approach involves cascading multiple LC PLLs to address the need for precise frequency tuning and improved phase noise performance. While this solution offers enhanced stability and jitter reduction, it incurs significant area and power consumption penalties. The added complexity of multiple PLL stages leads to higher integration costs, and the cascading of PLLs introduces additional coupling issues between stages, which can degrade the overall performance of the oscillator system. These challenges make this solution impractical for high-density applications.

A further typical approach to optimize LC oscillator performance is the use of multiple oscillators within a single LC PLL. In this solution, multiple oscillators are integrated into one PLL system to enhance frequency tuning capabilities and mitigate jitter. However, while this approach helps achieve finer frequency resolution, it introduces additional routing complexity and fails to eliminate the coupling issues that arise between oscillators. This creates additional challenges in maintaining the precision of the oscillator's phase noise and required random and deterministic jitter.

The multi-mode oscillator is another conventional approach aimed at increasing the frequency tuning range by incorporating a tunable inductor. This approach allows for an expanded frequency range, giving designers more flexibility in meeting varying application needs. However, the tradeoff for this added tunability is an increase in power consumption and area, as the additional components needed for tuning also add complexity to the design. Further, the tunable inductor introduces its own set of challenges, including nonlinearity and complexity in control circuits, which can degrade the overall performance of the LC oscillator and make it unsuitable for high-performance systems.

Despite these efforts, none of the current approaches fully address the challenge of optimizing the FOMT in LC oscillators. The solutions either introduce excessive power consumption, incur substantial area penalties, or fail to eliminate issues such as coupling and phase noise. As the demand for high-speed communication systems like 224G Ethernet grows, the need for innovative solutions that can balance performance, power, and area in a more effective manner becomes increasingly valuable. As such, a novel approach is needed that can not only extend the frequency tuning range but also mitigate the challenges associated with phase noise, jitter, and coupling, without significantly increasing the power consumption or area.

The examples address these challenges by using a circuit that incorporates resonant clock drivers and fractional frequency dividers to optimize frequency generation. Through the integration of multiple stages of resonant filtering, this approach aims to balance the tradeoff between tuning range, phase noise, and power consumption, offering a solution that meets the performance requirements of high-speed communication systems like 224G Ethernet.

The integration of resonant clock drivers and fractional frequency dividers following an LC oscillator offers a superior clocking solution for next-generation high-speed systems. By reducing phase noise, eliminating pulling effects, improving power efficiency, and enhancing signal integrity, this circuit architecture provides a scalable and reliable framework for high-performance communication applications.

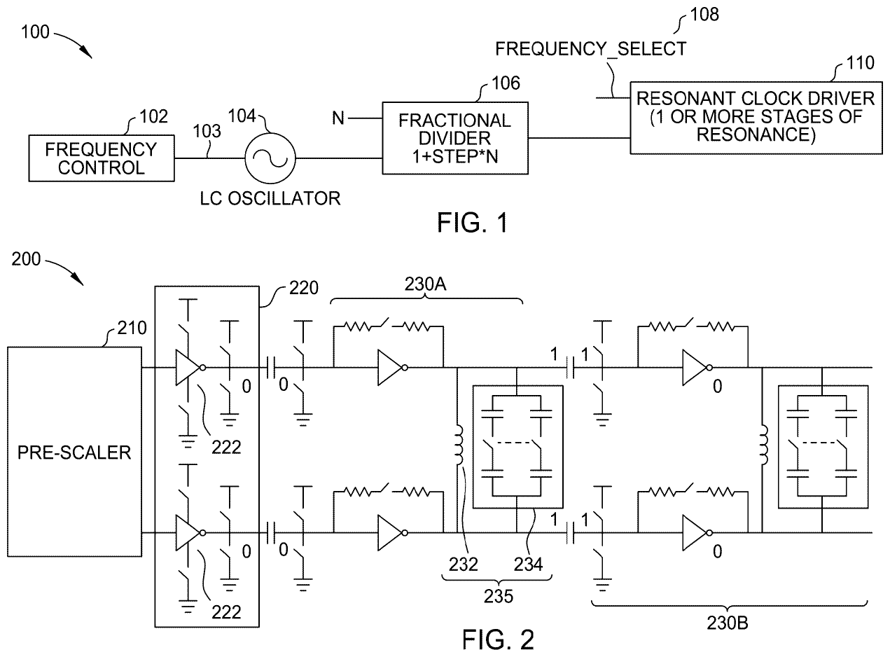

FIG. 1 illustrates a circuit including an LC oscillator, a fractional frequency divider, and a resonant clock driver, according to an example.

The circuit 100 includes a frequency controller 102, an LC oscillator 104, a fractional frequency divider 106, and a resonant clock driver 110 configured to receive a frequency_select signal 108.

The LC oscillator 104 is an electronic oscillator circuit that generates a periodic signal, usually a sine wave, by using an inductor (L) and a capacitor (C) in a resonant tank circuit. A resonant tank circuit is a combination of an inductor and a capacitor that stores and exchanges energy between magnetic and electric fields, generating oscillations at a specific resonant frequency. The resonant frequency is the natural frequency at which a system oscillates with maximum amplitude due to the energy exchange between two storage elements, such as an inductor and a capacitor. The LC oscillator 104 resonates at a specific frequency to filter unwanted signals. As such, the LC oscillator 104 relies on the principle of resonance, where energy oscillates between the magnetic field of the inductor and the electric field of the capacitor.

The LC oscillator 104 receives a frequency control signal 103 from the frequency controller 102, meaning that its frequency is adjusted based on an external source. One way to achieve this is through a phase-locked loop (PLL). The PLL is a closed-loop feedback system that continuously adjusts the frequency of the LC oscillator 104 to match a reference frequency. In one example, the PLL may include a phase detector, a low-pass filter, and a voltage-controlled oscillator.

The LC oscillator 104 is coupled to the fractional frequency divider 106, which is a circuit that divides the frequency of an input clock signal by a non-integer (fractional) value. Unlike an integer frequency divider, which divides by whole numbers (e.g., ÷2, ÷4, ÷8), a fractional divider allows division by values like 1.25, 1.5, 1.75, 2.5, or 3.125, etc., enabling fine-grained frequency control. The fractional frequency divider 106 can divide in ratios including 1, as well as 1+N*step, where the step is a fraction such as 0.25 or 0.5 or other fraction, and N can be an integer value greater than zero.

In one example, the fractional frequency divider 106 is a dual modulus pre-scaler. A dual-modulus pre-scaler alternates between two integer division ratios (e.g., ÷N and ÷(N+1)) in a controlled sequence. The switching is controlled by a fractional accumulator or sigma-delta modulator, which distributes the extra cycles over time. For example, to achieve ÷2.5, the pre-scaler alternates between ÷2 and ÷3 with a duty cycle that achieves the average. The duty cycle is the percentage of time a signal remains high (logic 1) during a single clock cycle. In another example, the fractional frequency divider 106 is a phase interpolator (fractional N-synthesis). Instead of directly dividing the clock, phase interpolation blends multiple clock phases to generate the fractional frequency. This may be used in high-speed serializer/deserializer (SerDes), clock multipliers, and digital PLLS.

The resonant clock driver 110 is a clock distribution circuit that uses resonance to improve power efficiency and reduce clock signal distortion. The resonant clock driver 110 achieves this by incorporating inductive (L) and capacitive (C) elements to create a resonant circuit that drives the clock network with minimal power loss. The circuit is designed so that the resonant frequency is adjustable based on a frequency_select signal 108. This ensures that the clock driver's output matches the frequency of the fractional frequency divider 106, which may be part of a PLL or clock synthesis system. The resonant clock driver 110 has a tunable frequency range to cover the required tuning range, such as, e.g., one octave range. An octave range refers to a frequency range where the upper frequency is twice the lower frequency.

The resonant clock driver 110 may have multiple stages of resonance. The resonant clock driver 110 filters and shapes the clock signal, improving phase noise, jitter, and duty cycle symmetry. When the resonant clock driver 110 includes multiple stages of resonance, it means that the system incorporates multiple LC resonators (tuned circuits) in a cascaded or coupled fashion to achieve better filtering and clock conditioning. Each stage of resonance helps in selective frequency enhancement (boosting the desired frequency component), jitter attenuation (reducing deterministic and random jitter from, e.g., a fractional frequency divider), duty cycle correction (filtering out duty cycle distortions caused by frequency dividers), harmonic rejection (suppressing unwanted harmonic content outside the target frequency band), and energy recycling (reducing power consumption by using LC tank circuits to resonate efficiently). Each stage acts as a bandpass filter tuned to the desired frequency. The cascaded stages refine the clock signal progressively.

The frequency_select (or frequency select) of a resonant clock driver is a control signal or parameter that determines the specific frequency at which the clock driver operates. The frequency_select signal 108 allows for tuning the resonant frequency of the clock driver to match the output frequency needed by the system. The frequency_select signal 108 adjusts the behavior of the resonant circuit in the clock driver, which includes components such as inductors, capacitors, and sometimes active elements like transistors, to create a resonant frequency that aligns with the desired clock signal frequency. The frequency_select signal 108 can also be used to match the output frequency of the fractional frequency divider 106. The fractional frequency divider 106 may generate a frequency that is a fraction of the input clock, and the resonant clock driver 110 ensures that its output matches this required frequency while maintaining signal integrity.

Therefore, in the circuit 100 a PLL generates a stable high-frequency clock and the frequency control signal 103 adjusts the PLL to set the LC oscillator frequency. The PLL ensures that the LC oscillator 104 starts at a controlled frequency. The LC oscillator 104 generates a clean, low-phase-noise wave (e.g., a sine wave) at the frequency dictated by the frequency control signal 103. The LC oscillator 104 provides better phase noise performance compared to ring oscillators. The LC oscillator 104 may generate a frequency higher than needed, so the fractional frequency divider 106 reduces it to a desired value. The fractional frequency divider 106 allows for fine frequency resolution beyond integer division. The fractional frequency divider 106 allows precise frequency tuning that the LC oscillator 104 alone cannot achieve and reduces frequency drift by adjusting the division ratio. The fractional frequency divider 106 provides a non-integer division ratio by alternating between two integer values over time. For example, if a 2.5× frequency division is needed, the circuit alternates between N=2 and N+1=3 over a modulation period.

However, the fractional frequency divider 106 introduces deterministic and random duty cycle error (DCE), demanding further conditioning. DCE refers to deviations from a perfect 50% duty cycle in a clock waveform. DCE can be random (due to thermal noise, process variations) or deterministic (caused by phase imbalance in the fractional divider). A poor duty cycle can amplify jitter in high-speed PLL and SerDes systems. The periodic switching between N and N+1 introduces timing variations, leading to DCE. The cause of the DCE in the fractional frequency divider 106 is from the fractional frequency divider 106 sometimes skipping or extending clock cycles to achieve an effective division ratio. The alteration between two integer division values introduces uneven cycle periods, leading to periodic timing variations. This periodically manifests as low-frequency phase modulation, which appears as spur tones in the frequency spectrum. DCE is an issue because it increases phase noise, and creates spurs and jitter in high-speed clocks.

As such, to reduce DCE, the resonant clock driver 110 is coupled to the fractional frequency divider 106. The resonant clock driver 110 filters phase noise, duty cycle distortion, and unwanted harmonics, acts as a bandpass filter, ensuring only the desired clock frequency is amplified, and maintains a near 50% duty cycle output clock. The 50% duty cycle means that we have a balanced clock. Stated differently, the duty cycle is maintained within a predetermined range. In other words, the resonant clock driver 110 produces a substantially symmetrical output clock signal or generates an output clock signal with a balanced high and low phase duration. Thus, the resonant clock driver 110 minimizes distortion in the output clock signal. An acceptable predetermined range for the duty cycle may depend of the application's tolerance for asymmetry. In one example, an acceptable predetermined range may be 45%-55%, which allows for a +/−5% tolerance from the ideal 50%. In yet another example, the acceptable range may be 48%-52%, which allows for a +/−2% tolerance from the ideal 50%. The acceptable predetermined range may be defined based on, e.g., the timing tolerance requirements of downstream circuitry. As such, the term “near” may be defined as within a specified range, e.g., +/−1%, +/−2%, +/−5%, etc. of the ideal 50%.

The resonant clock driver 110 is another LC circuit tuned to a frequency close to the fractional divider's output frequency. The resonant frequency is controlled by frequency_select signal 108 to match the fractional divider's output. The filtered waveform is then reshaped using inverters or buffers to generate a near-ideal clock. As such, the resonant clock driver 110 removes phase noise and deterministic jitter introduced by the fractional frequency divider 106. Stated differently, the resonant clock driver 110 mitigates DCE by acting as a bandpass filter tuned to the desired clock frequency.

The DCE of the output from the fractional frequency divider 106 before it reaches the resonant clock driver 110 can be measured. The DCE refers to the deviation from the ideal 50/50 high and low durations of the clock signal. In one example, to measure the DCE output from the fractional frequency divider 106, a high-resolution oscilloscope or timing analyzer can be used to observe the waveform at the frequency divider's output node, measuring the duration of the high and low phases over one or multiple clock cycles. The duty cycle error can then be calculated as DCE=|(T_high-T_ low)|/(T_high+T_low), where T_high and T_low represent the durations of the high and low portions of the clock, respectively. This yields a percentage deviation from the ideal 50% duty cycle. For instance, if T_high=5.5 ns and T_low=4.5 ns, the DCE would be 10%. By comparing the DCE before and after the application of mitigation techniques, the effectiveness of the circuit 100 configured to mitigate DCE can be empirically validated.

A similar measurement can be performed at the output of the resonant clock driver 110, which receives the potentially imbalanced clock from the fractional frequency divider 106. If the resonant clock driver 110 includes built-in correction mechanisms, the resulting waveform should exhibit reduced DCE. The same calculation is applied to determine the post resonant clock driver DCE. If the value is lower, this confirms that the circuit 100 is mitigating the error. One example method to measure the DCE from the resonant clock driver 110 is by using zero-crossing analysis. Another example involves capturing the resonant clock waveform using a high-bandwidth digital oscilloscope and then applying digital signal processing (DSP) techniques to extract timing parameters. In this method, multiple cycles of the waveform are digitized, peaks, troughs, and zero-crossings are identified, and timing intervals are calculated with various software tools. In yet another example, time interval analyzers or jitter analysis tools can directly measure duty cycle distortion in clock signals. These instruments may include features to define custom thresholds or crossing points and report DCE across multiple cycles.

The circuit 100 thus reduces figure of merit including tuning (FOMT), which is a metric used to evaluate the performance of the LC oscillator 104. The FOMT considers phase noise performance, power consumption, and tuning range (frequency agility). A finite FOMT means the LC oscillator 104 has limitations in either its tuning range, phase noise, or power efficiency. For example, a narrow tuning range limits the LC oscillator's ability to cover a wide range of frequencies. Increasing the tuning range may degrade phase noise, as larger tuning ranges involve lower quality factor (Q) varactors or switching mechanisms that introduce noise. Also, extending the tuning range or reducing phase noise often increases power consumption. As such, the FOMT is constrained in LC oscillators due to parasitic effects (affecting the tuning range), inductor Q (limiting phase noise reduction), and tuning range constraints (making it difficult to generate precise frequencies). The FOMT of the LC oscillator 104 of the circuit 100 is reduced by incorporating the fractional frequency divider 106 and the resonant clock driver 110 with the frequency_select signal 108 due to improved tuning efficiency, reduced phase noise, and minimized coupling effects.

The FOMT in the LC oscillator 104 of the circuit 100 is affected by a tradeoff between tuning range, phase noise, and power consumption. A wide tuning range demands a highly adjustable LC tank, which can degrade Q-factor and increase phase noise. A narrow tuning range improves phase noise but limits flexibility in frequency selection. This issue is problematic in 224G Ethernet, where precise high-speed clocking with minimal jitter and power overhead is needed. 224G Ethernet refers to the next-generation ultra-high-speed Ethernet standard targeting 224 Gbps per lane for data transmission. 224G Ethernet is a successor to 112G Ethernet and is being developed to meet the increasing bandwidth demands of artificial intelligence/machine learning (AI/ML) workloads, hyperscale data centers, high-performance computing (HPC), and advanced networking applications.

The fractional frequency divider 106 allows the LC oscillator 104 to operate at a higher frequency, where the LC tank performs better (higher Q-factor, lower phase noise). Instead of forcing the LC oscillator 104 to cover a wide tuning range, the fractional frequency divider 106 generates intermediate frequency steps without degrading the oscillator's Q-factor. This reduces the need for extreme varactor tuning, which would otherwise degrade phase noise. The fractional frequency divider 106 also allows the LC oscillator 104 to run at a fixed high-Q frequency while the fractional frequency divider 106 provides finer resolution clock outputs.

The resonant clock driver 110 acts as a bandpass filter, attenuating unwanted deterministic jitter and random jitter from the fractional frequency divider 106. The resonant frequency is controlled by frequency_select signal 108, ensuring that the resonance aligns with the desired output clock frequency. This resonance improves energy efficiency, allowing low-power clock regeneration while keeping a near 50% duty cycle. Stated differently, this refers to keeping the duty cycle within a predetermined range that is near the ideal 50% duty cycle. For example, the duty cycle can be maintained within +/−5% of the ideal 50%. By shaping the clock waveform and suppressing harmonics, the resonant clock driver 110 mitigates phase noise and enhances clock purity.

Moreover, in traditional LC oscillators, inductors introduce pulling effects due to electromagnetic coupling between adjacent oscillators. Pulling, coupling, or interference effects can degrade the performance of the oscillator system. These effects occur when adjacent PLLs or oscillators interact with each other through electromagnetic coupling, mutual inductance, or other forms of electrical interference.

Pulling occurs when the frequency of one oscillator is influenced or pulled by an adjacent oscillator. This can happen due to the mutual coupling of the oscillators, either inductively or capacitively. In other words, when two oscillators are placed too close together, the energy from one oscillator can affect the other, causing it to shift its frequency or phase slightly. This frequency or phase shift may not be desirable because it can introduce deterministic jitter and phase noise, thus reducing the precision of the clock signal.

Coupling refers to the interaction between two oscillators, which can occur through both electromagnetic fields and inductive coupling. When oscillators or PLLs are placed near one another, the magnetic fields generated by the current in one inductor can influence the inductors in the adjacent oscillator. This interaction can distort the desired frequency output, leading to jitter and poor phase noise performance. EMI is a subset of coupling, where high-frequency signals from nearby circuits or oscillators induce unwanted signals in the surrounding circuitry.

Interference can be caused by signals from nearby oscillators or PLLs that share common frequency ranges or harmonics, introducing noise into the system. Even if two oscillators are not directly coupled, their spurious signals or harmonics can overlap, leading to signal distortion or frequency instability in the output clock signal.

To minimize the risks of pulling, coupling, and interference effects, it is beneficial to manage the physical spacing between PLLs or oscillators.

As electromagnetic coupling between inductors increases when PLLs or oscillators are placed closer together, the magnitude of the mutual coupling-induced jitter becomes more significant. The jitter magnitude is inversely proportional to the frequency difference between adjacent oscillators. Therefore, when two oscillators are close in frequency, even small amounts of electromagnetic interference or coupling can cause significant fluctuations in the output frequency. By maintaining a larger frequency delta between adjacent PLLs, the coupling effect is weakened, reducing the jitter and ensuring that each PLL operates independently with minimal interference.

Phase noise, often manifested as deterministic jitter, is a direct result of the coupling effects between adjacent PLLs or oscillators. Tight coupling between oscillators can lead to fluctuations in their phase, causing more noise and reducing the accuracy of the output clock signal. A greater frequency separation reduces the chances of these oscillators locking into each other or influencing each other's phase noise, resulting in a cleaner output with less jitter and improved signal integrity.

Ensuring that PLLs or oscillators are spaced adequately apart from each other helps maintain system stability. When oscillators are too close, they may interact in unpredictable ways, causing frequency instability or phase drifting. Proper spacing ensures that each PLL can maintain a stable output without being pulled or influenced by neighboring circuits.

The circuit 100 mitigates these issues by decoupling frequency control from the LC oscillator 104 and introducing controlled resonance. Instead of making the LC oscillator 104 generate all output frequencies, the fractional frequency divider 106 synthesizes precise frequency steps from a fixed high-Q LC oscillator. This prevents the need for multiple adjacent oscillators, reducing electromagnetic coupling. It also allows wider frequency spacing between oscillators, minimizing the risk of pulling effects. The resonant clock driver 110 acts as a bandpass filter, isolating the clock signal from unwanted noise and harmonics. By tuning its resonance frequency (using frequency_select signal 108), the resonant clock driver 110 aligns precisely with the fractional divider output frequency. This ensures that only the desired clock signal is amplified, while any noise or interference is attenuated. The circuit 100 offers two selectable frequencies for a given output, reducing frequency proximity between oscillators. Since pulling jitter is inversely proportional to frequency separation, this minimizes jitter caused by pulling effects. As such, the fractional frequency divider 106 allows for a single, centralized LC oscillator, which results in reducing the number of LC tanks in the design and the resonant clock driver 110 isolates the output clock, which prevents unwanted interference. Electromagnetic coupling is thus significantly reduced, since fewer inductors operate in close proximity. The circuit 100 thus mitigates pulling, coupling, and interference effects and helps to manage the physical spacing between PLLs or oscillators.

The integration of resonant clock drivers and fractional frequency dividers following an LC oscillator offers several key benefits in high-speed clocking architectures, particularly for applications such as 224G Ethernet and other advanced communication systems. These advantages include improved signal integrity, reduced jitter, enhanced power efficiency, and minimized coupling effects.

The resonant clock driver acts as a bandpass filter, which selectively amplifies the desired frequency while attenuating unwanted noise components from the fractional frequency divider. By filtering deterministic and random DCEs, the system achieves a near 50% duty cycle, leading to improved clock stability and reduced jitter. Fractional frequency dividers introduce jitter due to interpolation, but the resonant clock driver smooths these variations, resulting in a cleaner output clock.

Traditional LC oscillators suffer from a FOMT limitation, where extending the tuning range degrades phase noise performance or increases power consumption.

Fractional frequency dividers allow for finer frequency granularity, reducing the need for a wide LC oscillator tuning range. Resonant clock drivers further refine the output, enabling narrowband operation at high efficiency.

EMI between adjacent oscillators or PLLs can cause pulling effects, where one oscillator inadvertently shifts the frequency of another. By integrating tunable resonant clock drivers, which can select between two frequency options for a given output, the frequency difference between adjacent oscillators is increased, reducing the impact of coupling-induced jitter. This approach allows PLLs to be placed closer together without degrading performance, leading to better scalability in high-speed transceiver designs.

In other words, in high-frequency systems, closely spaced PLLs and oscillators can suffer from pulling and coupling effects, where energy leakage between oscillators distorts their frequencies or phases. To mitigate these effects, the fractional frequency divider 106 and the resonant clock driver 110 can provide multiple valid frequency options for the same required output, ensuring that adjacent oscillators operate at alternating frequencies to reduce interference. The fractional frequency divider 106 allows a given frequency to be synthesized using different division sequences. By alternating between two division ratios, the system generates the required frequency while avoiding integer-related interference effects with adjacent oscillators.

For example, if the target frequency is 600 MHz, two valid division options from a 2.4 GHz oscillator can be to divide by 4 (i.e., 2.4 GHz÷4=600 MHz). A weighted divide by a 3 and 5 sequence (i.e., alternate between division ratios 3 and 5 in a controlled manner) can be used to maintain an effective 600 MHz output (ratio is 2000 MHz/600 MHz=3.3333, which is approximated using a weighted sequence of divide by 3 and divide by 5). If adjacent PLLs use different division sequences, they remain spectrally distinct, reducing pulling effects. Also, the resonant clock driver 110 can shift its resonance point by modifying L or C. By fine-tuning the tank circuit, two adjacent oscillators can operate at slightly different but functionally equivalent frequencies. For example, a required frequency of 1 GHz can be achieved using 1.002 GHz resonant tuning for one oscillator and 0.998 GHz resonant tuning for the adjacent oscillator. This prevents phase coupling.

High-speed interfaces such as 224G Ethernet need clean clock signals to avoid timing errors and data corruption. The circuit 100 ensures that the output clock has minimal phase distortion, making it ideal for high-speed SerDes, data converters, and wireless communication systems. A stable, low-noise clock improves bit error rate (BER) performance, enhancing the reliability of high-speed data links.

Traditional approaches that cascade multiple LC PLLs lead to higher area and power consumption due to additional inductors and routing complexity. The examples reduce the number of PLLs, leveraging resonant clock drivers and fractional dividers for frequency selection and filtering. This results in a compact, power-efficient architecture that is more scalable for advanced semiconductor process nodes and multi-lane transceiver designs.

Fractional frequency dividers allow for precise frequency control, enabling operation across multiple standards (e.g., 112G, 224G, or even future terabit-class Ethernet). Tunable resonant clock drivers support frequency adjustment, allowing real-time adaptation to different performance modes while maintaining optimal efficiency. This flexibility is beneficial for adaptive clocking systems in Al accelerators, data centers, and high-speed networking hardware.

FIG. 2 illustrates a resonant clock driver, according to an example.

The resonant clock driver 200 includes multiple stages of resonance. When the resonant clock driver 200 includes multiple stages of resonance, it means that the system incorporates multiple LC resonators (tuned circuits) in a cascaded or coupled fashion to achieve better filtering and clock conditioning. Resonance occurs when a system oscillates at its natural frequency with maximum amplitude due to the balance between energy stored in the inductive and capacitive components. In an LC circuit, resonance occurs when the inductive reactance (XL) and capacitive reactance (XC) are equal, causing the system to oscillate with minimal energy loss.

The resonant clock driver 200 may be one non-limiting example of the resonant clock driver 110 of FIG. 1. The resonant clock driver 200 includes a pre-scaler 210. The pre-scaler 210 is a frequency divider that supports both integer and fractional ratios. The pre-scaler 210 divides the input clock frequency before feeding it into the buffer stage 220. The pre-scaler 210 supports integer divide ratios for standard frequency scaling and also supports fractional divide ratios, which allow finer control over frequency adjustment.

The resonant clock driver 200 further includes a buffer stage 220 after the pre-scaler 210. The inverters 222 act as buffer stages to drive the next stage with sufficient signal strength. The inverters 222 ensure signal integrity and compensate for losses in the circuit and act as a signal amplifier before entering the resonance stage. After the buffer stage 220 is the first resonance stage 230A. The inductor 232 forms a parallel LC resonant circuit to selectively amplify the desired frequency. The inductor 232 stores magnetic energy, working in conjunction with the capacitor network 234 to resonate at the required frequency. The inductor 232 enhances energy efficiency by using resonance instead of a resistive drive to reduce overall power consumption. The inductor 232 and the capacitor network 234 acts as a resonant tank circuit. As stated above, the resonant tank circuit is a combination of L and C that stores and exchanges energy between magnetic and electric fields to generate oscillations at a specific resonant frequency.

The capacitor network 234 works with the inductor 232 to form a tunable LC tank circuit 235, setting the resonant frequency. The capacitor network 234 helps maintain a near 50% duty cycle by filtering out unwanted harmonics. The capacitor network 234 provides phase noise filtering and jitter reduction. The capacitor network 234 can include varactors or tunable capacitors for frequency selection. A varactor can also be referred to as a varicap diode, and is a type of semiconductor diode whose capacitance varies with applied reverse voltage. A varactor is operated in reverse bias, that is, negative voltage on the anode.

The capacitor network 234 can then be coupled to a second resonance stage 230B including further resonance tank circuits. The resonance stage is the portion of the circuit where the LC tank circuit 235 is located. The resonance stages filter unwanted frequency components, shape the clock signal, and enhance energy efficiency. For example, the resonance stages selectively amplify the desired clock frequency while attenuating noise and unwanted harmonics. The resonance stages further help maintain a 50% duty cycle by filtering out distortions from the previous circuit stages.

In operation, the clock signal from the fractional frequency divider 106 enters the inductor-capacitor (LC) tank circuit 235. The LC tank circuit 235 resonates at a specific frequency, filtering out unwanted components and producing a clean clock signal. The frequency_select signal 108 adjusts the capacitor network 234 to ensure that resonance aligns with the output of the fractional frequency divider 106. The output is a low-jitter, high-stability clock signal with an optimized duty cycle. By using the resonant clock driver 110 including multiple stages of resonance, it effectively cascades the two bandpass transfer functions to further attenuate random or deterministic jitter, including sinusoidal or other periodic jitter as well as DCD.

The resonant clock driver 200 reduces DCE uncertainty caused by the fractional frequency divider 106 by using LC resonance to generate a stable, low-jitter clock waveform. In the fractional frequency divider 106, the clock cycle varies due to the periodic toggling between division ratios (e.g., N and N+1), leading to edge placement variations. This variation introduces jitter and phase noise, impacting circuit timing. The resonant clock driver 200 smooths these transitions by maintaining a sinusoidal oscillation with high Q, reducing abrupt changes in edge placement and filtering out high-frequency jitter components. As such, since fractional frequency dividers can introduce cycle-to-cycle timing variations, the resonant clock driver 200 helps by ensuring consistent zero-crossing points for clock transitions, minimizing the impact of fractional divisions. This results in a more stable clock edge, reducing timing errors in synchronous circuits like PLLs and CDRs.

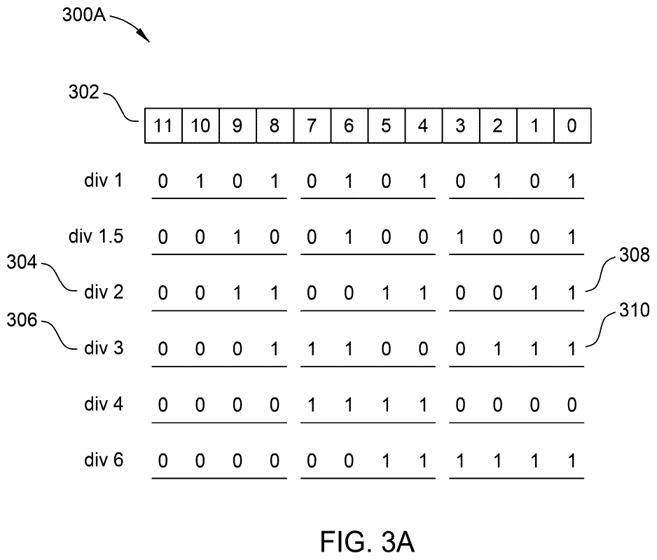

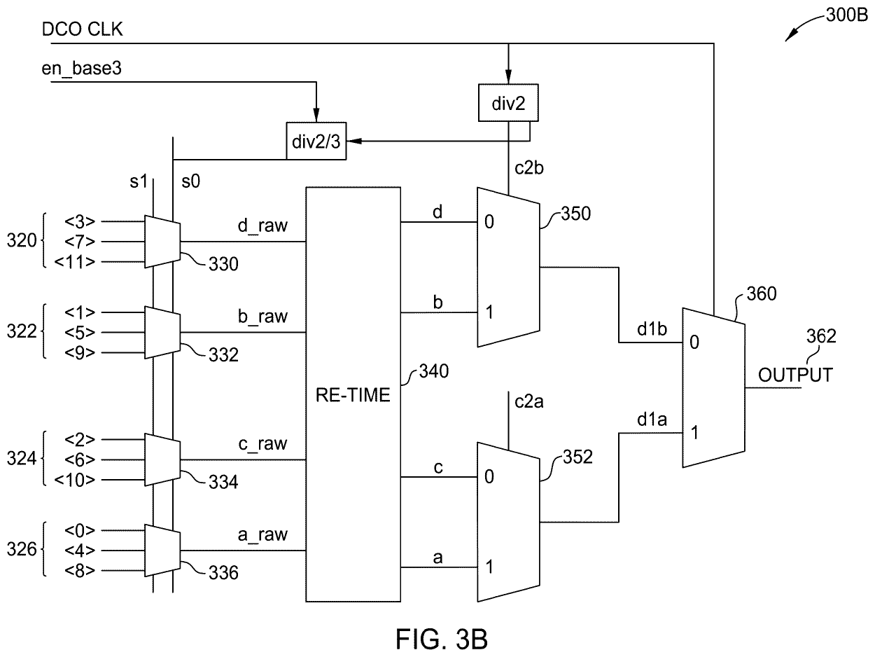

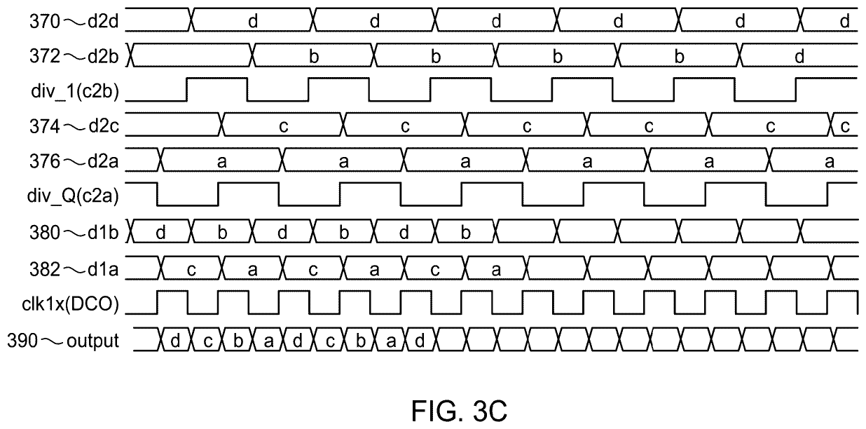

FIG. 3A illustrates a table with divide ratios, according to an example.

The table 300A includes divide ratios for the fractional frequency divider 300B of FIG. 3B. The table 300A lists the division factors used to generate an output frequency from an input clock. The fractional frequency divider 300B uses a combination of integer and fractional division to achieve non-integer divide ratios. The 0s and 1s in the table 300A represent a control sequence for selecting different integer divide values over time. This may be used with multi-modulus dividers or sigma-delta fractional-N PLLs, where the fractional frequency divider 106 switches between two or more integer values to achieve an effective fractional divide ratio. A multi-modulus divider is a clock driver that can switch between multiple integer divide values. The multi-modulus divider can be used in a fractional-N PLL to achieve fine frequency resolution. Such divider can switch between different modulus values based on a control signal. The sigma-delta fractional-N PLL divider uses sigma-delta modulation to control a multi-modulus divider. The sigma-delta modulator generates a control bit stream to drive a multi-modulus driver. The divide ratio is changed based on a noise-shaped pattern.

In the table 300A, the 0 selects one divide value (e.g., N) and the 1 selects another divide value (e.g., N+1). By toggling between these values in a controlled pattern, the average divide ratio over time approximates a fractional value. For example, the table 300A includes clock cycles 302. In one non-limiting example, there are 12 clock cycles. For a divide value of 2 (element 304), the control bits 308 may be 0011 0011 0011 (control bit stream). For a divide value of 3 (element 306), the control bits 310 may be 0001 1100 0111 (control bit stream). The control bit (0 or 1) determines whether the fractional frequency divider 300B applies N=2 or N+1=3. Over 12 cycles, the ratio of 2s and 3s may provide an average divide ratio of 2.5.

FIG. 3B illustrates a fractional frequency divider, according to an example.

The fractional frequency divider 300B may have a step of 0.5, which means that the fractional frequency divider 300B can generate output frequencies using half-integer divide ratios (e.g., 1.5, 2.0, 2.5, 3.0, etc.). This may be achieved using, e.g., a dual-modulus driver, which switches between two integer divide values to achieve an effective fractional division. As noted above with reference to FIG. 3A, to achieve an effective divide ratio of 2.5, the divider alternates between N=2 for some cycles and N+1=3 for other cycles. Using a binary control sequence of 0s and 1s, an output frequency of 2.5 can be achieved.

In one non-limiting example, first control bits 320 are input into a first multiplexer 330, second control bits 322 are input into a second multiplexer 332, third control bits 324 are input into a third multiplexer 334, and fourth control bits 326 are input into a fourth multiplexer 336. The first control bits 320 can be bits from cycles 3, 7, and 11. The second control bits 322 can be bits from cycles 1, 5, and 9. The third control bits 324 can be bits from cycles 2, 6, and 10. The fourth control bits 326 can be bits from cycles 0, 4, and 8. S1 and S0 represent the selection lines, which are used to choose which of the multiple input signals will be routed to the signal output. The outputs are fed to a re-time block 340.

The re-time block 340 (or re-time circuit) is used to reduce timing uncertainty, align signals, or stabilize data transitions before further processing. The multiplexers (MUX) select between multiple inputs, and the switching process can cause glitches or timing variations at the output. The re-time block 340 can ensure a clean, stable signal by sampling the MUX output on a clock edge. The re-time block 340 can be a flip-flop or a register.

The re-time block 340 receives outputs d_raw from the first multiplexer 330, b raw from the second multiplexer 332, c_raw from the third multiplexer 334, and a_raw from the fourth multiplexer 336. These signals are raw signals. The raw signals may exhibit timing variations, jitter, and phase noise due to transmission imperfections. The re-time block 340 outputs clean signals d, b, c, and a. The output signals d and b (clean signals) are fed to a multiplexer 350 and the output signals c and a (clean signals) are fed into a multiplexer 352. The output of the multiplexer 350 is d1b and the output of the multiplexer 352 is d1a. The output signals d1b and d1a are then fed into the multiplexer 360, which provides the output frequency 362. If the divider alternates between N=2 for some cycles and N+1=3 for other cycles, then using binary control sequences of 0s and 1s, an output frequency of 2.5 can be achieved.

The LC oscillator 104 can be a fairly narrow range design to optimize performance. The LC oscillator 104 can cover at least a 1.5× range if the step=0.5 with some additional margin for error terms. By combining the LC oscillator 104 with the fractional frequency divider 106, the frequency range can be extended to more than 2×. However, dividing by 1.5 or other fraction may result in poor DCE, which will not meet performance requirements. The resonant clock driver 110, when optimized and tuned using the frequency_select signal 108 to the target frequency, can attenuate the DCE, such that the output clock is nearly ideal 50% duty cycle. The net result is that the circuit 100 has a much higher FOMT than conventional techniques.

In one example, a fractional frequency divider by 1.5 means that the output clock frequency is ⅔ of the input clock frequency. Since 1.5 is not an integer, the fractional frequency divider alternates between two integer divide ratios in a controlled sequence. If the input is 300 MHz and the output needs to be 200 MHz, in the divide by 1 cycle, the output stays high 33.3% of the time (3.33 ns) and in the dive by 2 cycle, the output stay low for 66.6% of the time (6.66 ns). The result is a duty cycle oscillating between 33.3% and 66.6%. The duty cycle is corrected using the resonant clock driver 110, which adjusts the duty cycle back to about 50%. A 1.5 fractional divider is merely presented for illustrative purposes. The fractional divider may be in the order of 1.25, which means the output frequency is ⅘ of the input frequency. Any type of fractional divider may be used to tune the LC oscillator 104 across a wider frequency range. The frequency range of the LC oscillator 104 is the span of frequencies it can generate while maintain stable oscillations. Expanding this range means increasing the tunable frequency bandwidth, allowing the LC oscillator 104 to cover a broader spectrum of output frequencies.

Besides enabling wider frequency range, the examples may enable two or more options for the oscillator clock frequency to cover a single required output clock frequency. This means that multiple frequency configurations can be combined or selected to generate a single required output clock frequency in the LC oscillator 104.

So, if the required output frequency falls between two achievable integer division values, the system switches between them in a controlled pattern. That is, if an oscillator provides 100 MHz and the desired frequency is 40 MHz, if no direct division ratio exists, the system can alternate between (50 MHz; divide by 2) and (33.3 MHz; divide by 3) in a weighted pattern to achieve an effective 40 MHz output. In another example, if step=0.5, a 14 GHz output clock may be covered by 21 GHz divided by 1.5, as well as 14 GHz divided by 1.0. If step=0.25, a 14 GHz output clock can be covered by 17.5 GHz divided by 1.25, and 14 GHz divided by 1.25. Using multiple options thus helps mitigate DCE by distributing phase variations across different modulation patterns.

Stated differently, by enabling two options for a given output frequency, the design effectively mitigates the pulling effects caused by electromagnetic coupling between inductors or other coupling effects in the oscillator system. These coupling effects, particularly EMI or mutual inductance, can introduce unwanted jitter, degrading the oscillator's phase noise performance. The magnitude of this coupling jitter is inversely proportional to the frequency delta between two adjacent oscillators in the system. By offering multiple frequency options for a given output, the frequency separation between the oscillators can be increased, reducing the extent of the coupling and thus minimizing the jitter induced by electromagnetic interactions.

This strategy ensures that the oscillators are not too closely tuned, preventing the resonant circuits from interfering with each other and allowing for improved frequency stability and phase noise performance. The larger frequency gap effectively reduces the mutual inductive effects, leading to a cleaner, more stable output clock.

This approach is particularly beneficial in high-performance applications, such as 224G Ethernet or other high-speed communication systems, where even small amounts of jitter can significantly impact overall system reliability and signal integrity. The ability to mitigate coupling jitter through frequency selection provides a solution for maintaining signal quality without incurring significant additional power or area penalties.

FIG. 3C illustrates a timing diagram, according to an example.

The timing diagram 300C depicts the outputs d, b, c, and a (clean signals) from the re-time block 340. The outputs may be designated as 370 (for d2d), 372(d2b), 374 (d2c), and 376 (d2a). The outputs d1b and d1a of the multiplexer 350 and the multiplexer 352 are designated as 380 (d1b ) and 382 (d1a). The output frequency 362 is designated as 390.

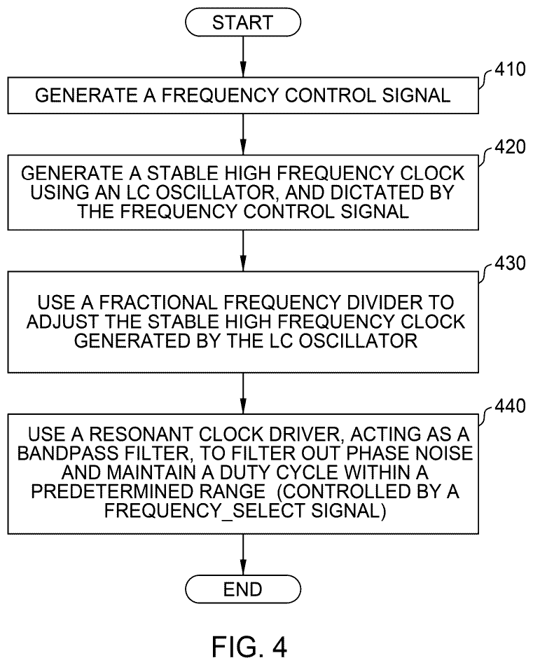

FIG. 4 illustrates a method for implementing the circuit including the LC oscillator, the fractional frequency divider, and the resonant clock driver, according to an example.

At 410, the frequency controller 102 generates a frequency control signal.

The frequency control signal adjusts the PLL to set the LC oscillator frequency. The PLL ensures that the LC oscillator starts at a controlled frequency.

At 420, the LC oscillator 104 generates a stable high frequency clock . The stable high clock frequency is dictated by the frequency control signal. The LC oscillator generates a clean, low-phase-noise sine wave at the frequency dictated by the frequency control signal.

At 430, the fractional frequency divider 106 is used to adjust the stable high frequency clock generated by the LC oscillator. The LC oscillator may generate a frequency higher than needed, so the fractional frequency divider reduces it to a desired value. The fractional frequency divider allows for fine frequency resolution beyond integer division. The fractional frequency divider allows precise frequency tuning that the LC oscillator alone cannot achieve. However, the fractional frequency divider introduces deterministic and DCE, demanding further conditioning.

At 440, the resonant clock driver 110, acting as a bandpass filter, is used to filter phase noise and maintain a near 50% duty cycle output clock (controlled by a frequency_select signal). The resonant clock driver is another LC circuit tuned to a frequency close to the fractional divider's output frequency. The resonant frequency is controlled by frequency_select to match the fractional divider's output. The filtered waveform is then reshaped using inverters or buffers to generate a near-ideal clock.

Therefore, according to FIGS. 1-4, the circuit 100 incorporates the LC oscillator 104, the fractional frequency divider 106, and the resonant clock driver 110 that can collectively achieve precise frequency synthesis while minimizing duty cycle distortion (DCD) and improving FOMT. The LC oscillator 104 serves as the core frequency source, leveraging an inductor (L) and capacitor (C) to generate a stable, low-phase-noise oscillation. However, when a precise fractional frequency is needed, the fractional frequency divider 106 is introduced. The fractional frequency divider 106 switches between integer division ratios, enabling fine frequency resolution and allowing two different division options to achieve a single output frequency.

The fractional frequency divider 106, while effective, introduces DCE due to the alternating division process. This results in jitter and duty cycle distortion, which can degrade signal integrity. To counteract this, a resonant clock driver 110 with multiple resonant stages is used. These resonant stages operate as bandpass filters, selectively amplifying and shaping the clock edges to restore signal integrity. By using the natural energy recycling of resonant circuits, the driver smooths timing variations and reduces phase noise, significantly improving DCD and overall clock quality. An advantage of the resonant clock driver 110 is its ability to provide two clock frequency options for a given output requirement. By tuning the resonance stages and adjusting the fractional divider's division sequence, the system can generate an effective frequency that closely matches the target while reducing switching losses and jitter. This approach optimizes power efficiency while maintaining low-noise characteristics. Another advantage is the use of a single oscillator instead of multiple oscillators (and instead of using ring oscillators).

In conclusion, the integration of resonant clock drivers and fractional frequency dividers following an LC oscillator architecture presents an efficient solution to overcoming the limitations imposed by the FOMT in conventional oscillator-based clocking systems. By using a controlled resonant frequency selection mechanism, the proposed design optimizes the phase noise, power consumption, and frequency tuning range tradeoffs inherent in LC oscillators. This approach enables improved spectral purity and stability, ensuring that high-speed communication systems, such as 224G Ethernet, achieve the necessary performance criteria.

An advantage of this architecture is its ability to eliminate pulling and coupling effects that typically arise due to EMI between adjacent oscillators or inductive components. Traditional solutions, such as cascading LC PLLs or integrating multiple oscillators within a single PLL, suffer from increased area, power overhead, and routing complexity, while failing to mitigate unwanted coupling. By incorporating tunable resonant clock drivers, which act as bandpass filters, the example approach attenuates deterministic and random clock edge distortions originating from fractional dividers and prevents the degradation of signal integrity.

Furthermore, the ability to select between two frequency options for a given output frequency effectively mitigates oscillator pulling effects. Since the magnitude of coupling jitter is inversely proportional to the frequency difference between adjacent oscillators, this dual-option mechanism ensures that the PLLs can be spaced more closely without experiencing performance degradation. This allows for a more compact, power-efficient, and scalable clocking solution, which is beneficial for high-speed digital interfaces that demand stringent timing accuracy and low phase noise.

Overall, the integration of LC-based fractional dividers and resonant clock drivers introduces a robust framework for achieving high-frequency precision with minimal jitter and coupling interference. By addressing the core challenges of tuning range limitations, phase noise, and power efficiency, this example approach enables a more reliable and scalable clocking architecture for high-speed transceivers and emerging communication standards.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product.

Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as J ava, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

1. A circuit comprising:
an LC oscillator configured to receive a frequency control signal;
a fractional frequency divider coupled to the LC oscillator; and
a resonant clock driver coupled to the fractional frequency divider, the resonant clock driver configured to mitigate duty cycle error (DCE) introduced by the fractional frequency divider by acting as a bandpass filter tuned to a frequency of an output of the fractional frequency divider.

2. The circuit of claim 1, wherein the fractional frequency divider provides a non-integer division ratio by alternating between two integer values over time.

3. The circuit of claim 1, wherein the fractional frequency divider divides in ratios including 1, as well as 1+N*step, where step is a fraction including 0.25 or 0.5 or other fraction, and N is an integer value greater than zero.

4. The circuit of claim 1, wherein the resonant clock driver is configured to remove phase noise and deterministic jitter introduced by the fractional frequency divider.

5. The circuit of claim 1, wherein the resonant clock driver is configured to filter phase noise, duty cycle distortion, and unwanted harmonics to maintain a duty cycle within a predetermined range.

6. The circuit of claim 1, wherein the resonant clock driver has multiple stages of resonance, wherein each stage of resonance is configured to provide selective frequency enhancement, jitter attenuation, duty cycle correction, and harmonic rejection.

7. The circuit of claim 1, wherein the resonant clock driver is configured to receive a frequency select signal to match an output frequency of the fractional frequency divider.

8. The circuit of claim 1, wherein the fractional frequency divider includes a first set of multiplexers configured to receive control bit streams and re-time circuitry configured to remove timing variations, jitter, and phase noise from input signals.

9. The circuit of claim 8, wherein a second set of multiplexers are coupled at an output end of the re-time circuitry to further process the input signals and provide an output frequency for a selected division ratio.

10. A circuit comprising:
an LC oscillator coupled to a fractional frequency divider; and
a tunable resonant clock driver coupled to the fractional frequency divider, the tunable resonant clock driver configured to act as a bandpass filter tuned to a frequency of an output of the fractional frequency divider to maintain a duty cycle within a predetermined range.

11. The circuit of claim 10, wherein the resonant clock driver is further configured to mitigate duty cycle error (DCE) introduced by the fractional frequency divider.

12. The circuit of claim 10, wherein the fractional frequency divider provides a non-integer division ratio by alternating between two integer values over time.

13. The circuit of claim 10, wherein the fractional frequency divider divides in ratios including 1, as well as 1+N*step, where step is a fraction including 0.25 or 0.5 or other fraction, and N is an integer value greater than zero.

14. The circuit of claim 10, wherein the resonant clock driver is configured to remove phase noise and deterministic jitter introduced by the fractional frequency divider.

15. The circuit of claim 10, wherein the resonant clock driver has multiple stages of resonance, wherein each stage of resonance is configured to provide selective frequency enhancement, jitter attenuation, duty cycle correction, and harmonic rejection.

16. The circuit of claim 10, wherein the resonant clock driver is configured to receive a frequency select signal to match an output frequency of the fractional frequency divider.

17. A method comprising:
generating a frequency control signal;
setting an LC oscillator frequency dictated by the frequency control signal;
adjusting the LC oscillator frequency using a fractional frequency divider; and
filtering phase noise and maintaining a duty cycle within a predetermined range using a resonant clock driver acting as a bandpass filter tuned to a frequency of an output of the fractional frequency divider, the resonant clock driver controlled by a frequency select signal.

18. The method of claim 17, wherein the resonant clock driver is further configured to mitigate duty cycle error (DCE) introduced by the fractional frequency divider.

19. The method of claim 17, wherein the fractional frequency divider provides a non-integer division ratio by alternating between two integer values over time.

20. The method of claim 17, wherein the resonant clock driver has multiple stages of resonance, wherein each stage of resonance is configured to provide selective frequency enhancement, jitter attenuation, duty cycle correction, and harmonic rejection.
